(19) United States
(12) Patent Application Publication
(10) Pub. No.: US 2011/0156775 A1
(43) Pub. Date: Jun. 30, 2011

(54) PHASE LOCK LOOP DEVICE AND CONTROL METHOD THEREOF

(76) Inventor: Pei-Si WU, Kao Hsiung City (TW)

(21) Appl. No.: 12/982,438

(22) Filed: Dec. 30, 2010

(30) Foreign Application Priority Data
Dec. 31, 2009 (TW) 098146441

(51) Int. Cl. H03L 7/08

(52) U.S. Cl. 327/156

(57) ABSTRACT

A phase lock loop device and a control method is disclosed in the present invention. The phase lock loop device includes a phase lock loop circuit and a memory unit. The phase lock loop generates a phase lock clock signal according to a control voltage. The memory unit couples the phase lock loop circuit. The memory unit provides an initial signal to the phase lock loop circuit for recovering the control voltage to a preset value according to a digital value while the phase lock loop circuit is enabled.

### BACKGROUND OF THE INVENTION

(a) Field of the Invention

The invention relates to a phase lock loop device, particularly to a phase lock loop device having short phase lock time.

(b) Description of the Related Art

FIG. 1 A shows a schematic diagram of a prior phase lock loop device. The phase lock loop device 10 comprises a phase detector 11, a charge pump 12, a loop filter 13, a voltage control oscillator (VCO) 14, and a divider 15. The divider 15 performs frequency division on the phase lock clock signal generated by the voltage control oscillator 14 and feeds back to the phase detector 11. The phase detector 11 detects the difference between input and feedback signal and provides the control signal to the charge pump 12 to thereby generate a control current. The control current charges/discharges the capacitors C1 and C2 through the loop filter 13 to generate the voltage Vc on the node 132 and apply to the voltage control oscillator 14. From the phase lock loop device 10 is enabled till the frequency of its signal is locked, it needs a period of phase lock time to charge the voltage on the node 132 to a target value. Generally, charging operation is started from 0V or VDD. Referring to FIGS. 1A and 1B, charging operation from 0V is used as an example for illustration. When the voltage on the node 132 be gradually charged from 0V to the target voltage Vc, the phase lock clock signal outputted by the phase lock loop device 10 reaches the target value Fvco to lock the frequency. In other words, the charging operation takes a time length t1 for locking the frequency, hence the phase lock loop device 10 takes long phase lock time to lock frequency every time. Thus, result in slowing down the speed of the whole system.

### BRIEF SUMMARY OF THE INVENTION

One object of the present invention is to provide a phase lock loop device capable of quickly restarting after the power is disabled.

One object of the present invention is to provide a phase lock loop device having quick recovery time.

One embodiment of the present invention provides a phase lock loop device. The phase lock loop device comprises a phase lock loop circuit and a memory unit. The phase lock loop circuit generates a phase lock clock signal according to a control voltage. The memory unit is coupled to the phase lock loop circuit. The memory unit provides an initial signal to the phase lock loop circuit for recovering the control voltage to a preset value according to a digital value while the phase lock loop circuit is enabled.

Another embodiment of the invention provides a circuit for storing a control voltage and locking a frequency signal. The circuit comprises a voltage control oscillator, a memory unit, and a control circuit. The voltage control oscillator generates a frequency signal according to a control voltage. The control circuit generates the control voltage according to an initial signal and adjusts the control voltage correspondingly while the frequency of the frequency signal changes so as to lock the frequency signal at a preset value. The memory unit stores the digital value of the control voltage after conversion and, during a preset duration, provides the initial signal substantially equals the control voltage to the control circuit according to the digital value.

Another embodiment of the invention provides a phase lock loop device. The phase lock loop device comprises a phase detector, a charge pump, a loop filter, a voltage control oscillator, and a memory unit. The phase detector detects a phase difference between a reference signal and a phase lock clock signal and generates a control signal according to the phase difference. The charge pump generates a control current according to the control signal. The loop filter generates a control voltage according to the control current. The memory unit, coupled to a node, is to store the control voltage as a digital value during a first preset duration and generate an initial signal according to the digital value during a second preset duration. The voltage control oscillator, coupled to the node, is to generate the phase lock clock signal according to the control voltage during the first preset duration and generate the phase lock clock signal according to the initial signal during the second preset duration.

Another embodiment of the invention provides a method for controlling a phase lock loop device. The method comprises the following steps. At first, a control voltage is provided to a phase lock loop. A phase lock clock signal is generated according to the control voltage and a digital value is generated according to the control voltage. Then, the digital value is stored. While the phase lock loop device is enabled, the digital value is converted into an initial signal and supplied to the phase lock loop device to provide the control voltage.

Another embodiment of the invention provides a method for controlling a phase lock loop device. The method comprises the following steps. At first, an initial signal is generated according to a preset digital value. Then, a control voltage is recovered to a preset voltage value according to the initial signal and the control voltage is applied to a phase lock loop. Finally, a phase lock clock signal is generated according to the control voltage.

The phase lock loop device and its control method according to the embodiments of the invention utilize the digital value, converted from the control voltage, to be stored in the memory unit to solve the problems raised by prior phase lock loop. In the present embodiments, before or when the phase lock loop device is enabled, the control voltage can be generated according to the digital value to quickly lock the frequency to generate the phase lock clock signal. Thus, unlike the prior art, long charging/discharging operation time is not needed while the phase lock loop device is recovered. Therefore, the phase lock loop device and its control method according to the embodiments of the invention can solve the problem in the prior art to achieve the purpose of speeding up locking the frequency of the phase lock loop device.

### BRIEF DESCRIPTION OF THE DRAWINGS

FIG. 1A shows a schematic diagram of a conventional phase lock loop device.

FIG. 1B shows a schematic diagram illustrating the operating waveform of the conventional phase lock loop device.

FIG. 2A shows a schematic diagram illustrating a phase lock loop device according to one embodiment of the present invention.

FIG. 2B shows a schematic diagram illustrating the operating waveform of the phase lock loop device shown in FIG. 2A.

FIG. 2C shows a schematic diagram illustrating a phase lock loop device according to one embodiment of the present invention.

FIG. 3 shows a schematic diagram illustrating a phase lock loop device according to one embodiment of the present invention.

FIG. 4 shows a schematic diagram illustrating a phase lock loop device according to one embodiment of the present invention.

FIG. 5 shows a flow chart illustrating a control method for a phase lock loop device according to one embodiment of the present invention.

FIG. 6A shows a schematic diagram illustrating a phase lock loop device according to one embodiment of the present invention.

FIG. 6B shows a schematic diagram illustrating the operating waveform of the phase lock loop device shown in FIG. 6A.

FIG. 7A shows a schematic diagram illustrating the configuration of the memory unit and the loop filter according to one embodiment of the present invention.

FIG. 7B shows a schematic diagram illustrating the configuration of the memory unit and the loop filter according to one embodiment of the present invention.

FIG. 8 shows a flow chart of a control method for a phase lock loop device according to one embodiment of the present invention.

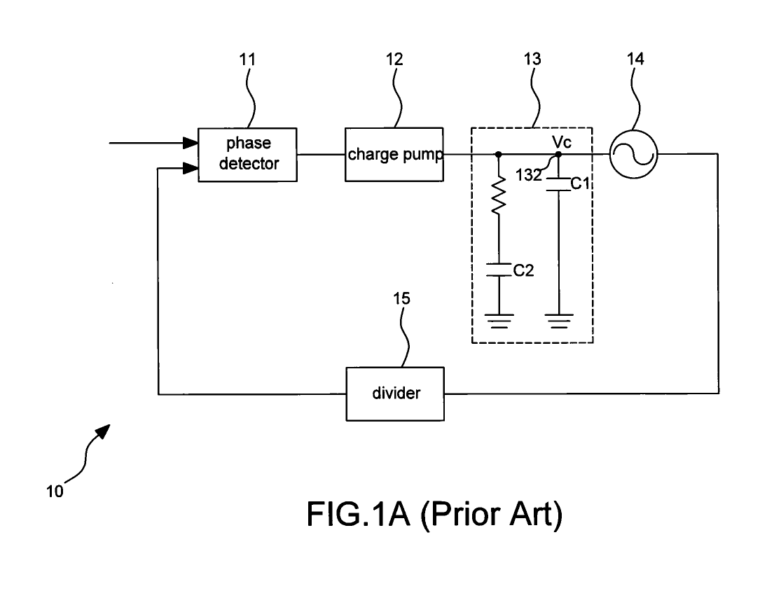

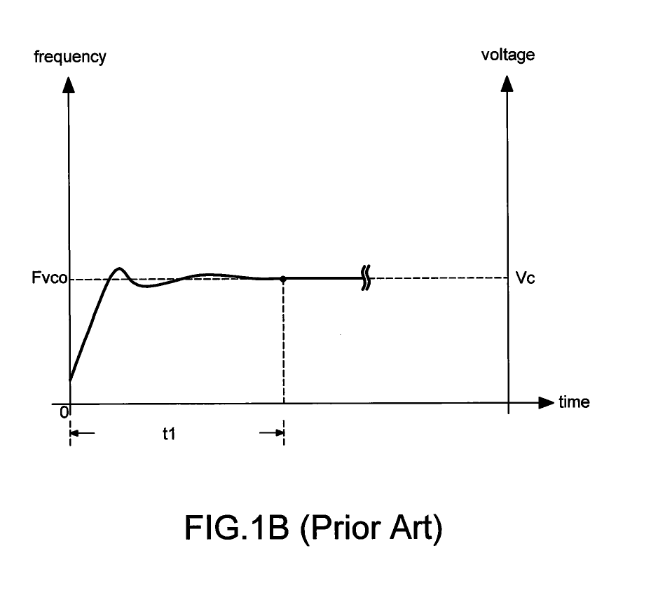

### DETAILED DESCRIPTION OF THE INVENTION

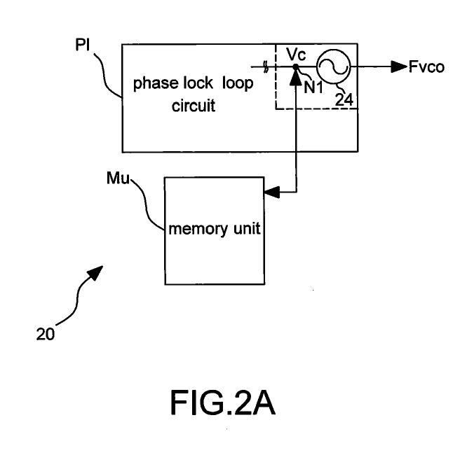

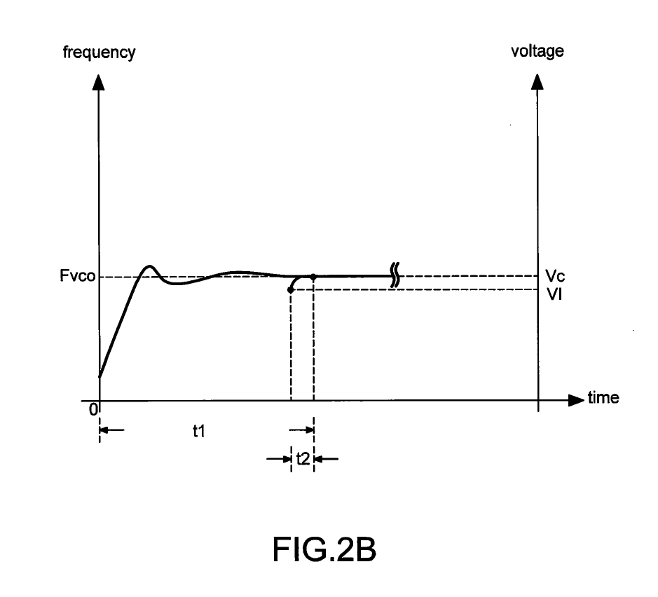

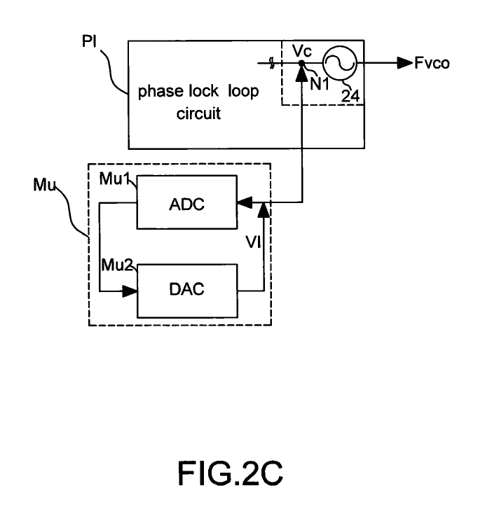

FIG. 2A shows a schematic diagram illustrating a phase lock loop device according to one embodiment of the invention. The phase lock loop device 20 can be a frequency-generating device or a circuit for storing a control signal (voltage or current, etc.) and locking the frequency of an output clock signal. The phase lock loop device 20 comprises a phase lock loop circuit P1 and a memory unit Mu. According to the control voltage Vc, the phase lock loop circuit P1 generates a phase lock clock signal Fvco. The voltage Vc should be ideal hold by a capacitance, however, in a real circuit, the voltage stored in a capacitance not only gradually leaks to 0V or VDD, but also be changed by the environment interferences, hence the present embodiment provides a preset voltage through a digital code. As the phase lock loop circuit P1 is enabled, the memory unit Mu supplies an initial signal to the phase lock loop circuit P1 according to a digital value for quickly raising the control voltage Vc to a preset voltage value. The operation details of this embodiment will be described in the following.

The phase lock loop circuit P1 comprises a voltage control oscillator 24 for outputting a phase lock clock signal Fvco with a stable frequency according to the control voltage Vc. It should be noted that the phase lock loop circuit P1 according to this embodiment may be a current phase lock loop circuit or a similar circuit to be developed in the future. Those who are skilled in the art should understand the configuration and operation method. Thus, their details will not be given hereinafter. The memory unit Mu is coupled to the node N1. While the phase lock loop circuit P1 is in operation and disable duration, the control voltage Vc is stored with a form of a digital value in the memory unit Mu. While the phase lock loop circuit PI is disabled and then enabled again, according to the digital value, an initial signal (for example an initial voltage) is provided to the node N1. Since the initial voltage is generated according to the digital value, the voltage level is closed to the control voltage Vc. The memory unit Mu can provide the initial voltage to the node N1 in an instant that the phase lock loop circuit P1 is enabled so that the voltage on the node N1 can be quickly recovered to its original level. In other words, the phase lock time needed for the phase lock loop circuit P1 is shortened. It should be noted, while the phase lock loop circuit P1 is enabled, in operation, and/or disabled, the memory unit Mu can also store the control voltage Vc as a digital value and converts the digital value to generate the initial voltage. That is, before the phase lock loop circuit P1 is enabled again (recovered), the initial voltage is prepared in advance. In other words, the memory unit Mu can provide the initial voltage before the phase lock loop circuit P1 is enabled again or provide the initial voltage at the same time the phase lock loop circuit P1 is enabled.

In this embodiment, the initial signal provided by the memory unit Mu according to the digital value is a voltage signal. In another embodiment, the memory unit Mu may also provide an initial current according to the digital value to achieve the same effect of shortening the phase lock time.

The phase lock time of the phase lock loop device 10 according to the prior art is compared with that of the phase lock loop device 20 shown in FIG. 2A. As shown in FIG. 2B, the phase lock loop device 10 according to the prior art takes a time length t1 during enabled to charge the voltage on the node N1 from 0V to a preset value Vc so as to lock the frequency to Fvco. On the contrary, according to the invention, while enabled, the phase lock loop device 20 instantly receives the initial voltage VI provided by the memory unit based on a digital value on the node N1. Thus, it only takes the time length t2 to charge the voltage on the node N1 from the initial voltage VI to the preset value Vc. Compared to the phase lock loop device 10, the phase lock loop device 20 according to the invention can remarkably reduce the length of the phase lock time.

The digital value can be determined by detecting the voltage on the node N1 after the phase lock loop device 20 is enabled for the first time. The digital value can also be updated by detecting the voltage on the node N1 after the phase lock loop device 20 is locked each time. In another embodiment, the memory unit Mu can pre-store the digital value but not need to detect the voltage on the node N1 so that the memory unit Mu can provide the initial signal according to the pre-stored (preset) digital value while the phase lock loop device 20 is enabled each time. It should be noted that the combination of detecting the voltage on the node N1 and using the preset digital value can be applied to the embodiments of the invention. For example, one of detecting the voltage on the node N1 and using the preset digital value can be the major control method and the other one is used according to some preset condition designated by a designer. For example, the preset condition is when the environment changes or the control voltage Vc is unstable. In another example, when the phase lock loop device 20 is enabled for the first time, the preset digital value is in use. The preset digital value is then updated according to the level of the control voltage after the phase lock loop device 20 is locked.

The phase lock loop device provided by the invention can effectively reduce the required phase lock time to solve the problem in the prior art while its circuits are enabled. The purpose of speeding up the recovery speed of the phase lock loop device can be achieved.

In one embodiment, as shown in FIG. 2C, the memory unit Mu comprises an analog-to-digital converter (ADC) Mu1 and a digital-to-analog converter (DAC) Mu2. The analog-to-digital converter Mu 1 converts the control voltage Vc into the corresponding digital value during the operation period of the phase lock loop circuit P1 and stores the digital value in a memory. In an instant that the phase lock loop circuit P 1 is enabled, the digital-to-analog converter Mu2 converts the digital value to generate the initial signal in a form of voltage or current. Since the digital value is stored in a digital form, the digital value does not disappear due to disabling the circuit. Thus, while the circuit is enabled each time, the digital-to-analog converter Mu2 can quickly provide the initial voltage or current to the phase lock loop circuit P1 according to the digital value.

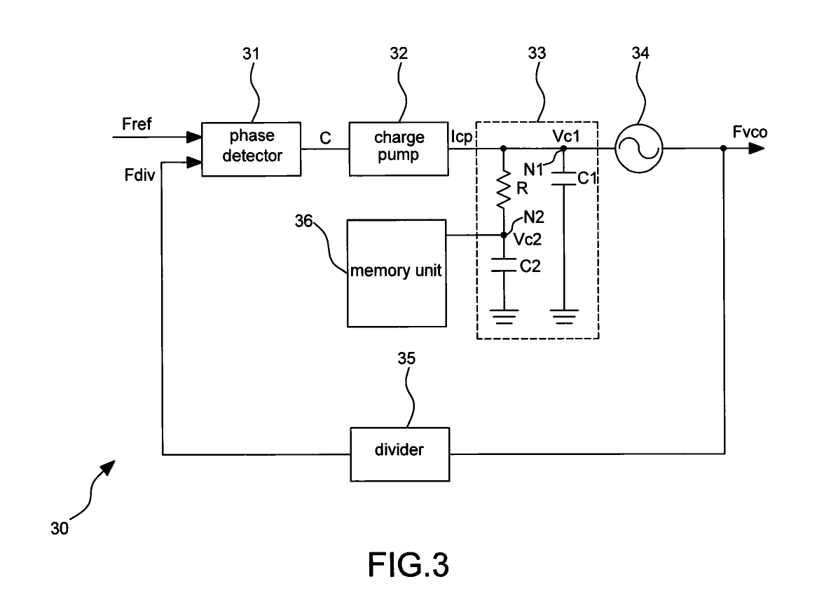

FIG. 3 shows a schematic diagram illustrating a phase lock loop device according to another embodiment of the invention. The phase lock loop device 30 comprises a phase detector 31, a charge pump 32, a loop filter 33, a voltage control oscillator 34, a divider 35 and a memory unit 36. The phase detector 31 compares the feedback signal Fdiv provided by the divider with the reference signal Fref so as to generate the control signal C to control the charge pump 32. The charge pump 32 generates control current Icp to charge or discharge the capacitors C1 and C2 in the loop filter 33 so that the loop filter 33 provides the control voltage Vc1 on the node N1 to the voltage control oscillator 34. In this embodiment, the phase detector 31, the charge pump 32, and the loop filter 33 form the control circuit of the phase lock loop device 30 to provide the control voltage to the voltage control oscillator 34 for outputting the phase lock clock signal Fvco. When the phase of the feedback signal Fdiv is leading that of the reference signal Fref, the control signal C controls the charge pump 32 to generate a negative control current Icp and let the voltage level of the control voltage Vc1 decrease. On the contrary, when the phase of the feedback signal Fdiv is lagging that of the reference signal Fref, the control signal C controls the charge pump 32 to generate a positive control current Icp and let the voltage level of the control voltage Vc1 increase. Thus, the output phase lock clock signal can be locked at a certain value.

In this embodiment, the phase detector 31, the charge pump 32, the loop filter 33, the voltage control oscillator 34 and the divider 35 can be implemented by any current technique or any technique with the similar function to be developed in the future. Those who are skilled in the art should understand their configuration and operation method. In order to avoid unnecessary ambiguity, the details of these elements will not be given hereinafter. In the above, the divider 35 is used to lower the frequency of the phase lock clock signal Fvco to provide the feedback signal for feedback control and can be omitted according to the design option.

In one embodiment, the capacitance of the capacitor C2 may be set to be larger than that of the capacitor C1. Thus, while the phase lock loop device 30 is in operation, the voltage level of the voltage Vc2 on the node N2 is very close to that of the voltage Vc1 on the node N1 but the voltage Vc2 is more stable than the voltage Vc1. Therefore, based on the consideration of protecting the memory unit 36 and increasing the stability, the memory unit 36 in this embodiment is coupled to the node N2. In another embodiment, the memory unit 36 can also be coupled to the node N1. In addition, since the node N2 is coupled to the capacitor C2, according to a digital value, the memory unit 36 in this embodiment provides the initial signal in the form of current to the node N2 to charge the capacitor C2 while the phase lock loop device 30 is enabled, so that the phase lock time can be shorten. As described in the above, the digital value in the memory unit 36 of this embodiment can be a preset (pre-store) digital value stored in the memory unit 36; can be determined by detecting the voltage Vc2 on the node N2 while the phase lock loop device 30 is enabled for the first time; or can be updated by detecting the voltage Vc2 on the node N2 after the phase lock loop device 30 functions steadily each time. In one embodiment, the memory unit set a look-up table storing a plurality of values corresponding to the voltage of the node N1 or N2. Thus, the memory unit can find a value from the look-up table according to the voltage on the node N1 or N2 and store it.

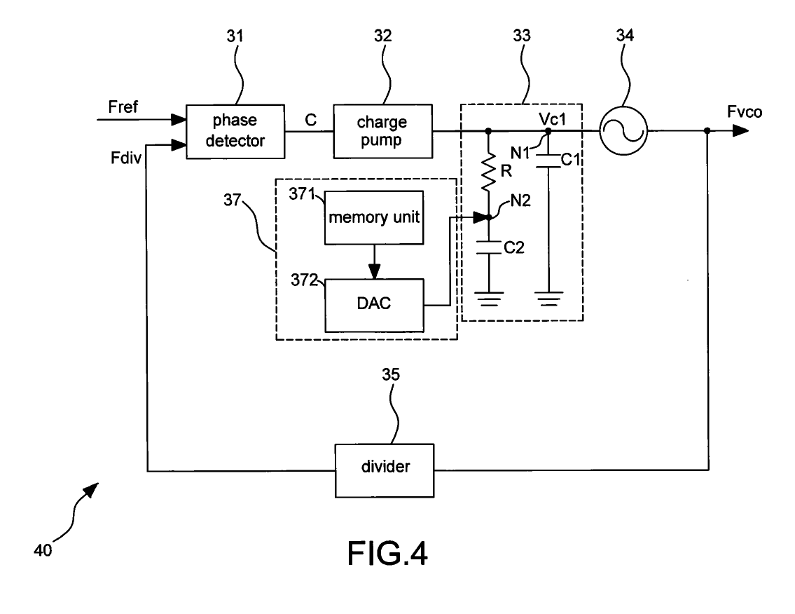

FIG. 4 shows a schematic diagram illustrating a phase lock loop device according to another embodiment of the invention. The configuration of the phase lock loop device 40 is similar to that of the phase lock loop device 30 shown in FIG. 3. The difference is that the memory unit 37 of the phase lock loop device 40 comprises a memory 371 and a digital-to-analog converter 372. The memory 371 stores a preset digital value. While the system is enabled, the digital-to-analog converter 372 converts the preset digital value in the memory 371 and supplies the initial signal to the node N2 so that the phase lock loop device 40 can be quickly enabled again. In another embodiment, a look-up table can be stored in the memory 371.

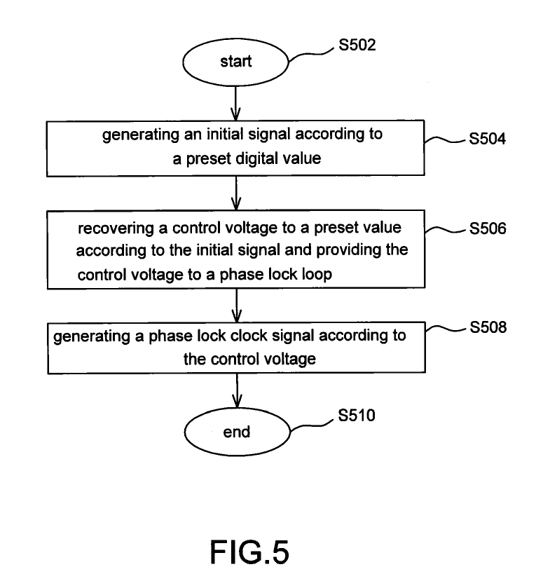

FIG. 5 shows a flow chart illustrating a control method according to one embodiment of the invention. The method comprises the following step:

Step S502: start;
Step S504: generating an initial signal according to a preset digital value;
Step S506: recovering a control voltage to a preset value according to the initial signal and providing the control voltage to a phase lock loop;
Step S508: generating a phase lock clock signal according to the control voltage;

Step S510: end.

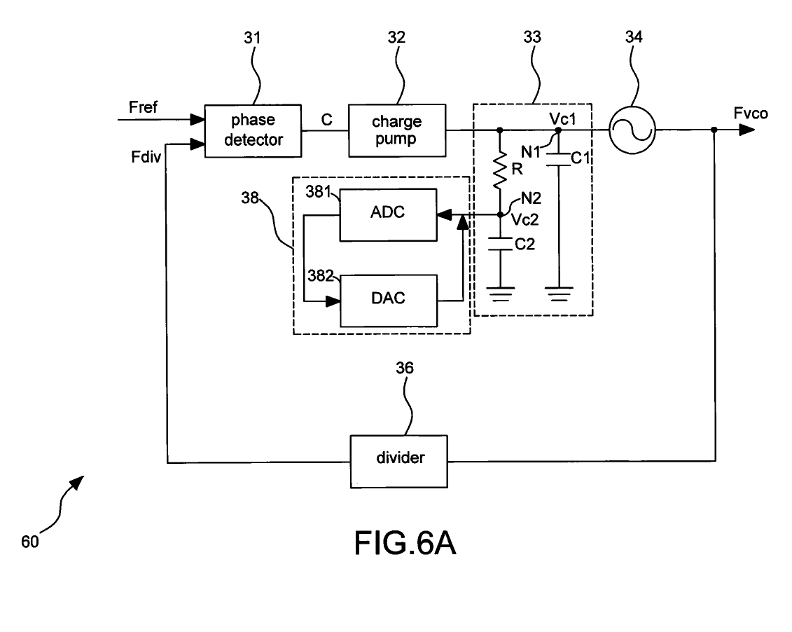

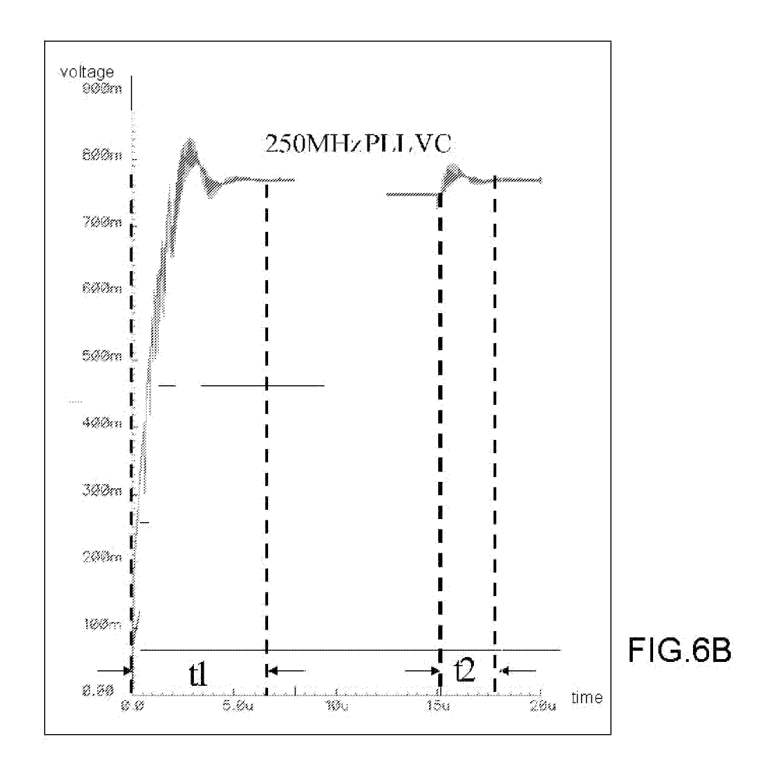

FIG. 6A shows a schematic diagram illustrating a phase lock loop device according to another embodiment of the invention. The memory unit Mu of the phase lock loop device 60 comprises an analog-to-digital converter 381 and a digital-to-analog converter 382. When the control voltage on the node N1 reaches Vc1, the voltage on the node N2 is Vc2. Then, the analog-to-digital converter 381 receives the voltage Vc2 and converts the voltage Vc2 to generate and store a digital value. The analog-to-digital converter 381 can comprise a non-volatile memory to store the digital value. After that, when the phase lock loop device 60 is disabled and then enabled again, the digital-to-analog converter 382 converts the digital value to generate the initial signal and provides the initial signal to the node N2 (for example, voltage Vc2 or current to the node N2). At the time, the phase lock loop device 60 can use the voltage Vc2 to quickly recover the voltage on the node N1 to Vc1 to achieve the purpose of locking the frequency. It should be noted that the time length of enabling the phase lock loop device 60 for the first time is t1 and the time length for the second time is t2. As shown in FIG. 6B, t2 is much less than t1. The figure is an example of a simulation diagram generated by the 250 MHz phase lock loop device. On the left hand side of the figure, the waveform of charging from 0V till locking the frequency is shown and it takes the time length t1. On the right hand side of the figure, the waveform of charging from Vc2 (initial voltage) till locking the frequency is shown and it takes the time length t2. From FIG. 6B, it clearly shows that t2 is much less than t1.

Furthermore, the higher resolution the analog-to-digital converter 381 and the digital-to-analog converter 382 have, the voltage converted by the two converters is closer to the voltage Vc1. Besides, when the phase lock loop device 60 is disabled, the analog-to-digital converter 381 and the digital-to-analog converter 382 take only little power to execute their memory function. Therefore, the energy saving efficiency of the whole circuitry will not be affected.

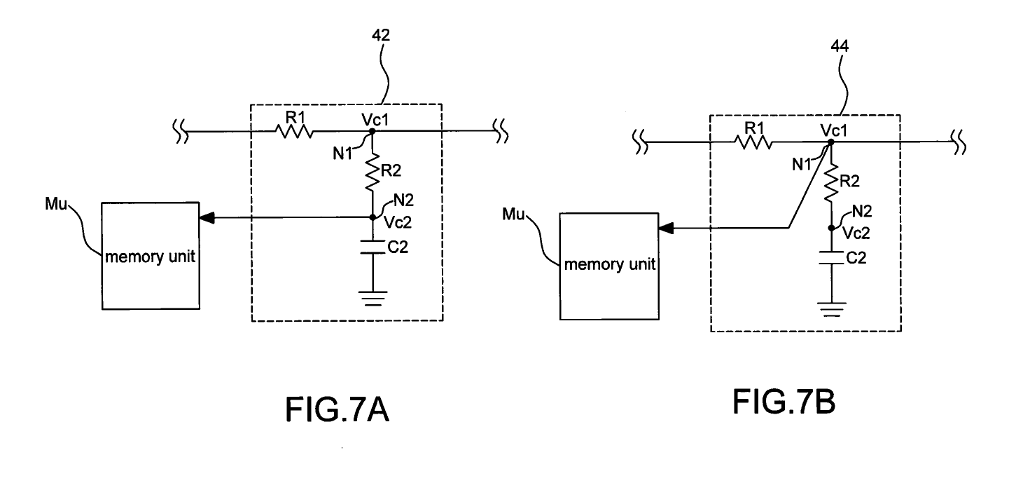

It should be noted that the loop filter in the embodiments of FIGS. 3, 4, and 6A can be used to stabilize the control voltage Vc1. But, the loop filter according to the invention is not limited to this type and any current or future loop filter can be used, such as the loop filter 42 shown in FIG. 7A and the loop filter shown in FIG. 7B. Besides, the memory unit of the invention is coupled to the loop filter. In FIGS. 3, 4, and 6A, the memory unit Mu is coupled to the filter element of the loop filter—the node between the resistor R and the capacitor C2. On the contrary, in another embodiment, the memory unit can be directly coupled to the node N1 and is not shown in FIGS. 3, 4, and 6A in order to avoid further complication. Those who are skilled in the art should understand the layout of FIGS. 3, 4, and 6A from FIG. 7A.

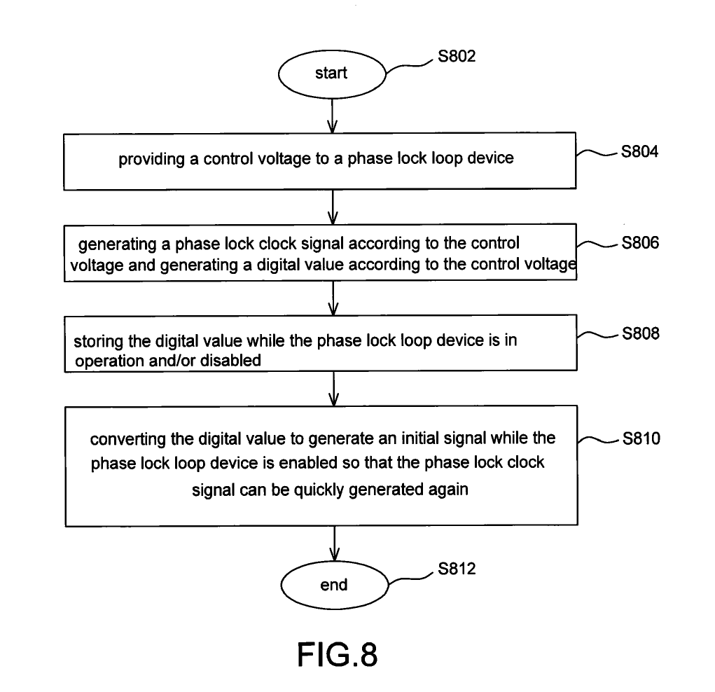

FIG. 8 shows a flow chart illustrating a control method according to one embodiment of the invention. The method comprises the following step:

Step S802: start;
Step S804: providing a control voltage to a phase lock loop device;
Step S806: generating a phase lock clock signal according to the control voltage and generating a digital value according to the control voltage;
Step S808: storing the digital value while the phase lock loop device is in operation and/or disabled;
Step S810: converting the digital value to generate an initial signal while the phase lock loop device is enabled so that the phase lock clock signal can be quickly generated again;

### Step S812: end.

Although the present invention has been fully described by the above embodiments, the embodiments should not constitute the limitation of the scope of the invention. Various modifications or changes can be made by those who are skilled in the art without deviating from the spirit of the invention.

What is claimed is:

1. A phase lock loop device, comprising:
a phase lock loop circuit, for generating a phase lock clock signal according to a control voltage; and
a memory unit, coupled to the phase lock loop circuit, for providing an initial signal to the phase lock loop circuit according to a digital value while the phase lock loop circuit is enabled, so as to recover the control voltage to a preset value.

2. The device according to claim 1, wherein the phase lock loop circuit comprises: a voltage control oscillator, coupled to the control voltage, for generating the phase lock clock signal according to the control voltage.

3. The device according to claim 1, wherein the memory unit comprises:
an analog-to-digital converter, for performing analog-to-digital conversion on the control voltage to generate the digital value; and
a digital-to-analog converter, for performing digital-to-analog conversion on the digital value to generate the initial signal.

4. The device according to claim 1, wherein the memory unit comprises:
a memory, for storing at least a preset digital value; and
a digital-to-analog converter, for performing a digital-to-analog conversion on the preset digital value to generate the initial signal.

5. The device according to claim 1, wherein the memory unit comprises:
a memory, comprising a look-up table, storing a plurality of corresponding values, for selecting a corresponding value according to the control voltage as the digital value; and
a digital-to-analog converter, for performing digital-to-analog conversion on the digital value to generate the initial signal.

6. The device according to claim 3, wherein the analog-to-digital converter comprises a non-volatile memory for storing the digital value.

7. The device according to claim 1, wherein the initial signal is in a voltage or current form.

8. The device according to claim 1, wherein the phase lock loop circuit comprises a loop filter for filtering and/or stabilizing the control voltage.

9. The device according to claim 8, wherein the memory unit is coupled to the loop filter.

10. A circuit for storing a control voltage and locking a frequency signal, the circuit comprising:
a voltage control oscillator, for generating a frequency signal according to a control voltage;
a control circuit, for generating the control voltage according to an initial signal and adjusting the control voltage correspondingly while the frequency of the frequency signal changes, so as to lock the frequency signal at a preset value; and
a memory unit, for storing a digital value converted from the control voltage, and providing the initial signal substantially equals the control voltage to the control circuit according to the digital value during a preset duration.

11. The circuit according to claim 10, wherein the memory unit comprises:
an analog-to-digital converter, for performing an analog-to-digital conversion on the control voltage to generate the digital value; and
a digital-to-analog converter, for performing a digital-to-analog conversion on the digital value during the preset duration to generate the initial signal.

12. The circuit according to claim 10, wherein the preset duration means a time period from the circuit turned off till re-enabling.

13. The circuit according to claim 11, wherein the analog-to-digital converter comprises a non-volatile memory for storing the digital value.

14. The circuit according to claim 10, wherein the control circuit comprises a loop filter for filtering and/or stabilizing the control voltage.

15. The circuit according to claim 14, wherein the memory unit is coupled to the loop filter.

16. The circuit according to claim 10, wherein the initial signal is voltage or current.

17. A phase lock loop device, comprising:
a phase detector, for detecting a phase difference between a reference signal and a phase lock clock signal, and generating a control signal according to the phase difference;
a charge pump, for generating a control current according to the control signal;
a loop filter, for generating a control voltage according to the control current;
a memory unit, coupled to a node, for storing the control voltage as a digital value during a first preset duration, and generating an initial signal according to the digital value during a second preset duration; and
a voltage control oscillator, coupled to the node, for generating the phase lock clock signal according to the control voltage during the first preset duration and generating the phase lock clock signal according to the initial signal during the second preset duration.

18. The device according to claim 17, wherein the first preset duration is the period for operating the phase lock loop device.

19. The device according to claim 17, wherein the second preset duration is the period from disabling the phase lock loop device till re-enabling the phase lock loop.

20. The device according to claim 17, wherein the memory unit comprises:
an analog-to-digital converter, for performing analog-to-digital conversion on the control voltage to generate the digital value; and
a digital-to-analog converter, for performing digital-to-analog conversion on the digital value to generate the initial signal.

21. The device according to claim 17, further comprising:
a divider, for lowering the frequency of the phase lock clock signal.

22. The device according to claim 20, wherein the analog-to-digital converter comprises a non-volatile memory for storing the digital value.

23. The device according to claim 17, wherein the initial signal is of voltage or current.

24. A method for controlling a phase lock loop device, the method comprising:
providing a control voltage to a phase lock loop;
signal generating step, generating a phase lock clock signal according to the control voltage and generating a digital value according to the control voltage;
storing the digital value; and
converting the digital value into an initial signal to the phase lock loop device while the phase lock loop device is enabled so that the control voltage is recovered to a preset value.

25. The method according to claim 24, wherein the control voltage and the initial signal are substantially the same.

26. The method according to claim 24, wherein there is a difference between the control voltage and the initial signal.

27. The method according to claim 24, wherein the signal generating step comprises:
selecting a corresponding value in a look-up table according to the control voltage as the digital value.

28. The method according to claim 24, wherein the signal generating step comprises:
performing analog-to-digital conversion on the control voltage to generate the digital value.

29. A method for controlling a phase lock loop device, the method comprising:
generating an initial signal according to a preset digital value;
recovering a control voltage to a preset voltage value according to the initial signal and applying the control voltage to a phase lock loop; and
generating a phase lock clock signal according to the control voltage.

30. The method according to claim 29, wherein the control voltage and the initial signal are substantially the same.

31. The method according to claim 29, wherein there is a difference between the control voltage and the initial signal.

32. The method according to claim 29, further comprising:
updating the preset digital value according to the control voltage.

33. The method according to claim 32, wherein the step of updating the preset digital value comprises:
selecting a corresponding value in a look-up table according to the control voltage to update the preset digital value.

34. The method according to claim 32, wherein the step of updating the preset digital value comprises:
performing analog-to-digital conversion on the control voltage to generate a digital value to update the preset digital value.
